(19) United States
(12) Patent Application Publication
(10) Pub. No.: US 2022/0352854 A1
(43) Pub. Date: Nov. 3, 2022

(54) POWER AMPLIFYING MODULE

(71) Applicant: Murata Manufacturing Co., Ltd., Kyoto (JP)

(72) Inventors: Yuki OHMAE, Kyoto (JP); Wataru TAKAHASHI, Kyoto (JP)

(21) Appl. No.: 17/660,898

(22) Filed: Apr. 27, 2022

(30) Foreign Application Priority Data
Apr. 28, 2021 (JP) 2021-076216

(51) Int. Cl. H03F 1/30; H03F 3/45

(52) U.S. Cl. CPC H03F 1/30; H03F 3/45475; H03F 2200/09

(57) ABSTRACT

In a power amplifying module in which a plurality of differential amplifying circuits is mounted on a substrate, each of the differential amplifying circuits includes a chip device that includes at least two amplifiers, each of the at least two amplifiers amplifying a differential signal, a balun that includes a primary side winding wire and a secondary side winding wire, both ends of the primary side winding wire being connected to an output of the chip device, and a capacitor provided between a power feed point of the primary side winding wire and a reference potential. In at least one of the plurality of the differential amplifying circuits, the distance from one end of the primary side winding wire to the power feed point is different from the distance from the other end of the primary side winding wire to the power feed point.

### CROSS REFERENCE TO RELATED APPLICATION

This application claims priority from Japanese Patent Application No. 2021-076216 filed on Apr. 28, 2021. The content of this application is incorporated herein by reference in its entirety.

### BACKGROUND ART

The present disclosure relates to power amplifying modules.

In a power amplifier installed in a wireless communication terminal device, the power of a single-ended signal (unbalanced signal) is amplified, and a single-ended signal is output. As an example of configuration of such a power amplifier, there is a differential amplifying circuit that converts a single-ended signal into a pair of differential signals (balanced signals), respectively amplifies these differential signals using two amplifiers, and converts amplified differential signals into a single-ended signal. In this configuration, the emitter inductance of a transistor for the differential signal becomes zero, and thus the gain of the power amplifier can be easily increased. Japanese Unexamined Patent Application Publication No. 8-18005 discloses a stable semiconductor integrated circuit capable of extracting differential signals in a balanced manner.

### BRIEF SUMMARY

In the differential amplifying circuit, there is an issue of asymmetry of differential signals caused by characteristic variations of amplifiers and the layout of components. Particularly, in the configuration in which differential amplifying circuits for a plurality of communication bands are installed in a single module, the asymmetry of differential signals is likely to occur due to interference between the differential amplifying circuits or the like.

The present disclosure realizes a power amplifying module that enables suppression of characteristic degradation caused by the asymmetry of differential signals.

A power amplifying module according to one aspect of the present disclosure is a power amplifying module in which a plurality of differential amplifying circuits is mounted on a substrate, wherein each of the differential amplifying circuits includes a chip device that includes at least two amplifiers, each of the at least two amplifiers amplifying a differential signal, a balun that includes a primary side winding wire and a secondary side winding wire, both ends of the primary side winding wire being connected to an output of the chip device, and a capacitor provided between a power feed point of the primary side winding wire and a reference potential, and in at least one of the plurality of the differential amplifying circuits, a distance from one end of the primary side winding wire to the power feed point is different from a distance from an other end of the primary side winding wire to the power feed point.

According to this configuration, it becomes possible to reduce the gain difference and the phase difference of differential signals and improve the asymmetry of differential signals. This enables suppression of the characteristic degradation caused by the asymmetry of differential signals.

According to the present disclosure, it becomes possible to realize a power amplifying module that enables suppression of the characteristic degradation caused by asymmetry of differential signals.

### BRIEF DESCRIPTION OF THE DRAWINGS

FIG. 1 is a schematic diagram illustrating one example of circuit block configuration of a power amplifying module according to an embodiment;

FIG. 2 is a diagram illustrating a differential amplifying circuit of a power amplifying module according to an embodiment;

FIG. 3A is a diagram illustrating an exemplary component layout that improves asymmetry of differential signals in a power amplifying module according to a first embodiment;

FIG. 3B is a diagram illustrating an exemplary component layout that improves asymmetry of differential signals in the power amplifying module according to the first embodiment;

FIG. 3C is a diagram illustrating an exemplary component layout that improves asymmetry of differential signals in the power amplifying module according to the first embodiment;

FIG. 4 is a diagram illustrating an improvement example of asymmetry of differential signals in the power amplifying module according to the first embodiment;

FIG. 5 is a diagram illustrating an exemplary component layout that improves asymmetry of differential signals in a power amplifying module according to a first modification example of the first embodiment;

FIG. 6 is a diagram illustrating an improvement example of asymmetry of differential signals in a power amplifying module according to the first modification example of the first embodiment;

FIG. 7 is a diagram illustrating an exemplary component layout that improves asymmetry of differential signals in a power amplifying module according to a second modification example of the first embodiment;

FIG. 8 is a diagram illustrating an improvement example of asymmetry of differential signals in a power amplifying module according to the second modification example of the first embodiment;

FIG. 9 is a diagram illustrating an improvement example of asymmetry of differential signals in a power amplifying module according to a comparative example;

FIG. 10A is a diagram illustrating an exemplary component layout that improves asymmetry of differential signals in a power amplifying module according to a second embodiment;

FIG. 10B is a diagram illustrating an exemplary component layout that improves asymmetry of differential signals in the power amplifying module according to the second embodiment;

FIG. 10C is a diagram illustrating an exemplary component layout that improves asymmetry of differential signals in the power amplifying module according to the second embodiment;

FIG. 10D is a diagram illustrating an exemplary component layout that improves asymmetry of differential signals in the power amplifying module according to the second embodiment;

FIG. 11A is a diagram illustrating an improvement example of asymmetry of differential signals in the power amplifying module according to the second embodiment;

FIG. 11B is a diagram illustrating an improvement example of asymmetry of differential signals in the power amplifying module according to the second embodiment; and

FIG. 12 is a diagram illustrating an exemplary layout of a plurality of differential amplifying circuits on a power amplifying module according to a third embodiment.

### DETAILED DESCRIPTION

Hereinafter, power amplifying modules according to embodiments are described with reference to the drawings. Note that the present disclosure is not limited by these embodiments.

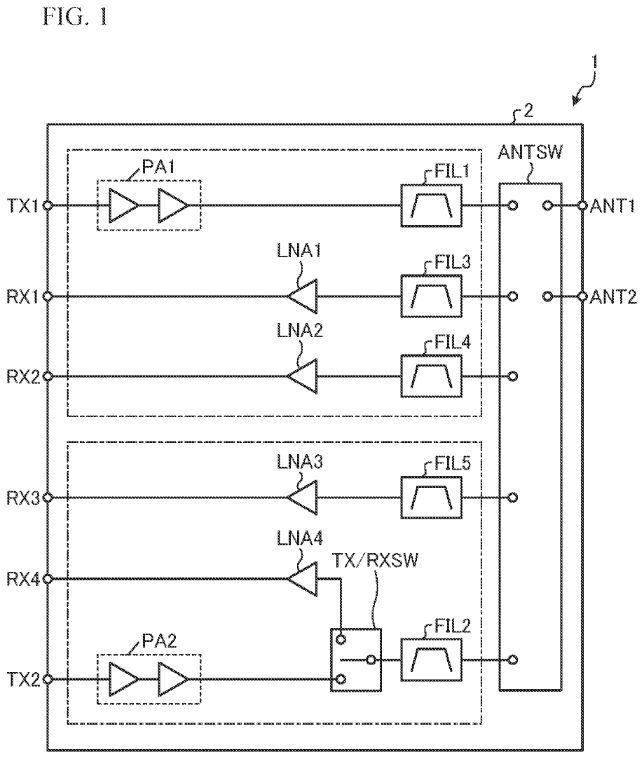

FIG. 1 is a schematic diagram illustrating one example of circuit block configuration of a power amplifying module according to an embodiment. A power amplifying module 1 according to the present embodiment is a microminiaturized integrated module in which a plurality of integrated circuits and various functional components mounted on a substrate 2 are unified. The substrate 2 is, for example, a ceramic multilayer substrate such as a low temperature co-fired ceramics (LTCC) substrate or the like. First, a circuit block configuration illustrated in FIG. 1 is described below.

As illustrated in FIG. 1, a front-end module 1 according to a first embodiment includes, as one example, a first power amplifier circuit (hereinafter, also referred to as “PA1”), a second power amplifier circuit (hereinafter, also referred to as “PA2”), a first low-noise amplifier (hereinafter, also referred to as “LNA1”), a second low-noise amplifier (hereinafter, also referred to as “LNA2”), a third low-noise amplifier (hereinafter, also referred to as “LNA3”), a fourth low-noise amplifier (hereinafter, also referred to as “LNA4”), a first filter circuit (hereinafter, also referred to as “FILL”), a second filter circuit (hereinafter, also referred to as “FIL2”), a third filter circuit (hereinafter, also referred to as “FIL3”), a fourth filter circuit (hereinafter, also referred to as “FIL4”), a fifth filter circuit (hereinafter, also referred to as “FIL5”), a transmission/reception switching circuit (hereinafter, also referred to as “TX/RXSW”), and an antenna switching circuit (hereinafter, also referred to as “ANTSW”).

PA1, LNA1, LNA2, FIL1, FIL3, and FIL4 perform, for example, transmission and reception of Band “n79”. PA2, LNA3, LNA4, FIL2, FIL5, and TX/RXSW perform, for example, transmission and reception of Band “n77”. Note that transmission frequency bands to be amplified by PA1 and PA2 are not limited to Band “n79” and Band “n77”.

PA1 amplifies a first transmission signal received by a transmission signal input terminal TX1. PA2 amplifies a second transmission signal received by a transmission signal input terminal TX2. In the present disclosure, PA1 and PA2 are each a differential amplifying circuit that converts a single-ended signal into a pair of differential signals (balanced signals), amplifies the differential signals, and converts the amplified differential signals into a single-ended signal.

PA1 and PA2 may each include, for example, bipolar transistors, or may each include, for example, field effect transistors (FETs). In the case where PA1 and PA2 each includes bipolar transistors, for example, heterojunction bipolar transistors (HBTs) are used. The present disclosure is not limited by the specific configurations of PA1 and PA2.

LNA1 amplifies a reception signal received by an antenna terminal ANT1 or ANT2 via FIL3. For example, in the circuit block configuration illustrated in FIG. 1, a reception signal amplified by LNA1 is output from a reception signal output terminal RX1.

LNA2 amplifies a reception signal received by the antenna terminal ANT1 or ANT2 via FIL4. For example, in the circuit block configuration illustrated in FIG. 1, a reception signal amplified by LNA2 is output from a reception signal output terminal RX2.

LNA3 amplifies a reception signal received by the antenna terminal ANT1 or ANT2 via FIL5. For example, in the circuit block configuration illustrated in FIG. 1, a reception signal amplified by LNA3 is output from a reception signal output terminal RX3.

In the circuit block configuration illustrated in FIG. 1, TX/RXSW switches between the transmission signal output from PA2 and the reception signal for LNA4. Specifically, TX/RXSW outputs the transmission signal output from PA2 to FIL2. Further, TX/RXSW outputs the reception signal, which is received by the antenna terminal ANT1 or ANT2 via FIL2, to LNA4.

LNA4 amplifies a reception signal received by TX/RXSW. For example, in the circuit block configuration illustrated in FIG. 1, the reception signal amplified by LNA4 is output from a reception signal output terminal RX4.

FIL1 performs filtering of the transmission signal output from PA1 and outputs a filtered signal to ANTSW.

FIL2 performs filtering of the transmission signal output from PA2 via TX/RXSW and outputs a filtered signal to ANTSW. Further, FIL2 performs filtering of the reception signal output from ANTSW and outputs a filtered signal to LNA4 via TX/RXSW.

ANTSW switches a transmission/reception path for a transmission signal and a reception signal. Specifically, ANTSW changes the output destination (antenna terminal ANT1 or ANT2) of the transmission signal received by FIL1. Further, ANTSW changes the output destination (antenna terminal ANT1 or ANT2) of the transmission signal received by FIL2. Further, ANTSW changes the output destination (FIL2, FIL3, FIL4, FIL5) of the reception signal received by the antenna terminal ANT1 or ANT2. Note that FIG. 1 illustrates the configuration including two antenna terminals ANT1 and ANT2 as an example. However, the number of the antenna terminals is not limited thereto.

The foregoing circuit block configuration illustrated in FIG. 1 is one example, and the present disclosure is not limited by the configuration of the power amplifying module 1 according to the embodiment.

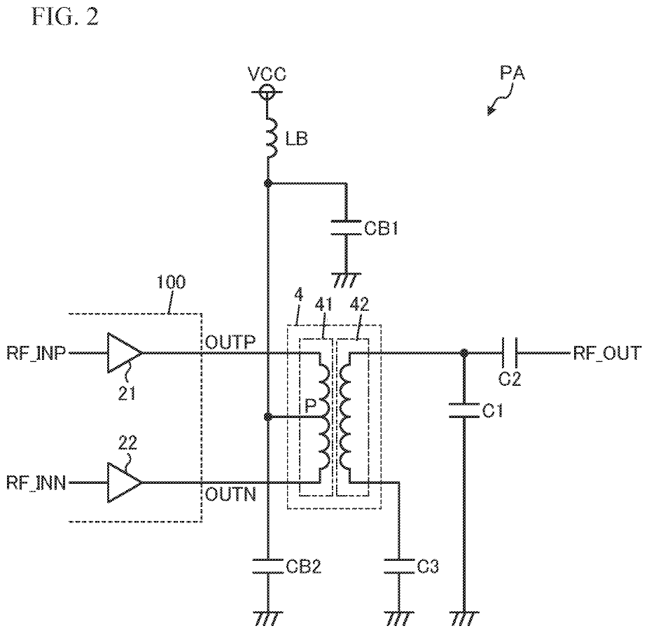

FIG. 2 is a diagram illustrating a differential amplifying circuit of a power amplifying module according to an embodiment. Note that in the following description, when the distinction between the first power amplifier circuit PA1 and the second power amplifier circuit PA2 is not discussed, the first power amplifier circuit PA1 and the second power amplifier circuit PA2 can be simply referred to as “differential amplifying circuit PA”. In the case where the distinction between the first power amplifier circuit PA1 and the second power amplifier circuit PA2 is discussed, the first power amplifier circuit PA1 can also be referred to as “differential amplifying circuit PA1”, and the second power amplifier circuit PA2 can also be referred to as “differential amplifying circuit PA2”.

In the present disclosure, the differential amplifying circuit PA includes a chip device 100 mounted on the substrate 2. The chip device 100 includes, for example, HBTs. The chip device 100 includes amplifiers 21 and 22. The amplifier 21 amplifies a differential signal RF_INP and outputs the amplified signal from an output OUTP of the chip device 100. The amplifier 22 amplifies a differential signal RF_INN and outputs the amplified signal from an output OUTN of the chip device 100.

On the periphery of the chip device 100, periphery circuit components of the differential amplifying circuit PA are installed. In the example illustrated in FIG. 2, an inductor LB and capacitors C1, C2, C3, CB1, and CB2 are (surface mounted device) SMD components mounted on a surface layer of the substrate 2. Further, a balun 4 includes a conductor provided on the surface layer or in one or more inner layers of the substrate 2.

The balun 4 includes an inductor 41 which is a winding wire on the primary side and an inductor 42 which is a winding wire on the secondary side. The inductor 41 and the inductor 42 are magnetically coupled with each other. One end of the inductor 41 is connected to the output OUTP of the amplifier 21. The other end of the inductor 41 is connected to the output OUTN of the amplifier 22.

A power supply potential VCC is supplied to a power feed point P of the inductor 41 via the inductor LB. The capacitors CB1 and CB2 are provided between the feed path of the power supply potential VCC and a reference potential (here, ground potential GND).

The capacitors C1 and C2 are components included in an output matching circuit of the differential amplifying circuit PA. Here, in a region where the transmission frequency band is high, such as in Band “n79”, sometimes, it fails to provide matching between the inductance value and the coupling coefficient of the balun 4. In the present disclosure, as illustrated in FIG. 2, it is desirable to provide impedance matching by employing a configuration in which a transmission signal RF OUT is output from one end of the inductor 42 connected to the output matching circuit and providing the capacitor C3 between the other end of the inductor 42 and a reference potential (here, ground potential GND). Note that in PA2 (see FIG. 1) whose target of amplification is Band “n77” whose transmission frequency band is lower than that of Band “n79”, the capacitor C3 is not necessarily included. Note that for PA2 whose target of amplification is Band “n77”, the circuit configuration illustrated in FIG. 2 may be used.

In such a differential amplifying circuit, there is an issue of asymmetry of differential signals caused by a factor such as a characteristic variation of amplifier or the like. Hereinafter, in the power amplifying module 1 according to the embodiment, configurations that suppress characteristic degradation caused by the asymmetry of differential signals are described.

### First Embodiment

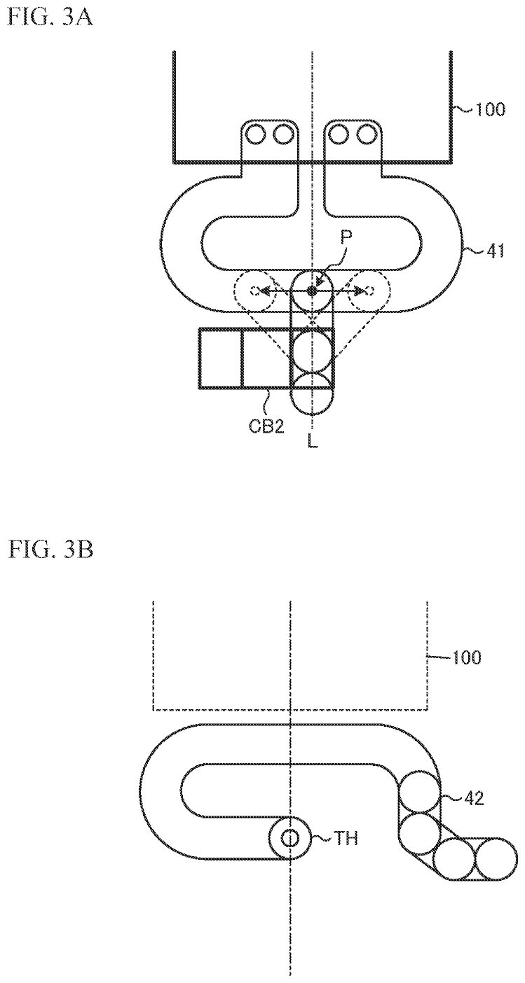

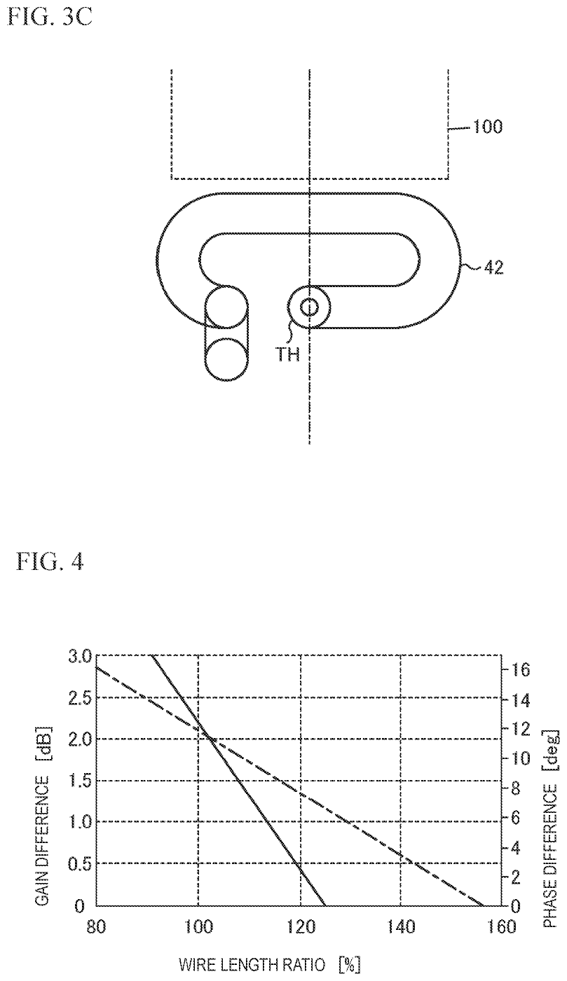

FIG. 3A, FIG. 3B, and FIG. 3C are each a diagram illustrating an exemplary component layout that improves the asymmetry of differential signals in a power amplifying module according to the first embodiment. FIG. 3A illustrates a surface layer pattern of the substrate 2 on which the chip device 100 and the SMD components are mounted, and FIG. 3B and FIG. 3C illustrate inner layer patterns of the substrate 2. The inner layer patterns of FIG. 3B and FIG. 3C are examples of the respective inner layer patterns in different layers.

As illustrated in FIG. 3A, in the first embodiment, the inductor 41 of the balun 4 is provided as the surface layer pattern of the substrate 2. Further, as illustrated in FIG. 3B and FIG. 3C, in the first embodiment, the inductor 42 of the balun 4 is provided as the inner layer patterns of the substrate 2. The inner layer pattern of the inductor 42 illustrated in FIG. 3B is connected to the inner layer pattern of the inductor 42 illustrated in FIG. 3C using a through hole TH.

In the first embodiment, the asymmetry of differential signals is improved by adjusting the ratio (hereinafter, also simply referred to as “wire length ratio”) between the distance from one end of the inductor 41 to the power feed point P of the power supply potential VCC and the distance from the other end of the inductor 41 to the power feed point P of the power supply potential VCC. Specifically, as illustrated in FIG. 3A, the distance from one end of the inductor 41 to the power feed point P of the power supply potential VCC is different from the distance from the other end of the inductor 41 to the power feed point P of the power supply potential VCC. In other words, the power feed point P of the power supply potential VCC is provided at a position deviated from a center line L that divides the wire length of the inductor 41 into two equal lengths. Note that the “distance” here means, for example, the “wire length”, and means the wire length from one end of the inductor 41 to the power feed point P of the power supply potential VCC and the wire length from the other end of the inductor 41 to the power feed point P of the power supply potential VCC.

FIG. 4 is a diagram illustrating an improvement example of asymmetry of differential signals in the power amplifying module according to the first embodiment. In FIG. 4, the horizontal axis represents the wire length ratio of the inductor 41, and the vertical axis represents the gain difference and the phase difference between differential signals. The solid line illustrated in FIG. 4 depicts the gain difference between differential signals, and the dashed line depicts the phase difference between differential signals.

As illustrated in FIG. 4, by adjusting the wire length ratio of the inductor 41, it becomes possible to reduce the gain difference and the phase difference of differential signals and improve the asymmetry of differential signals. This enables suppression of the characteristic degradation caused by the asymmetry of differential signals.

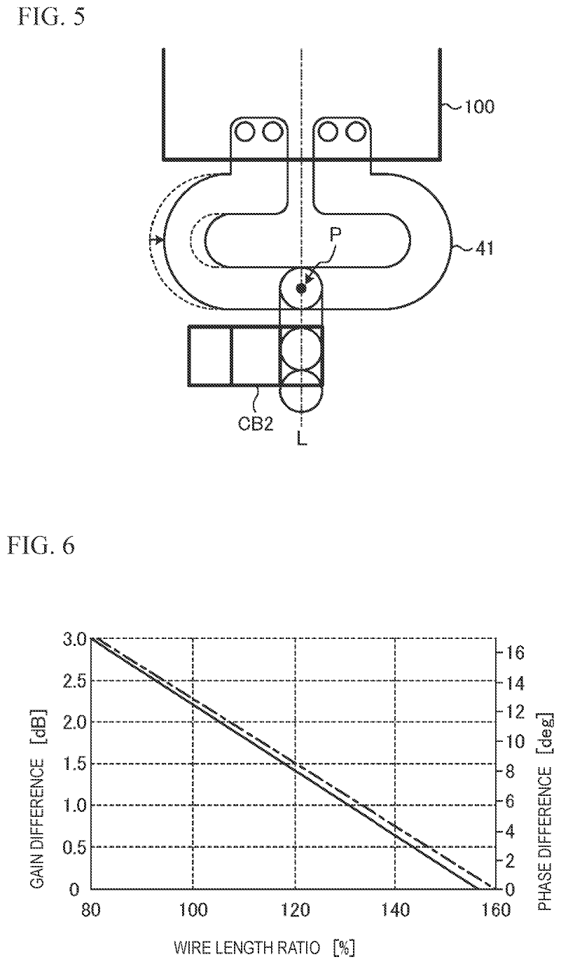

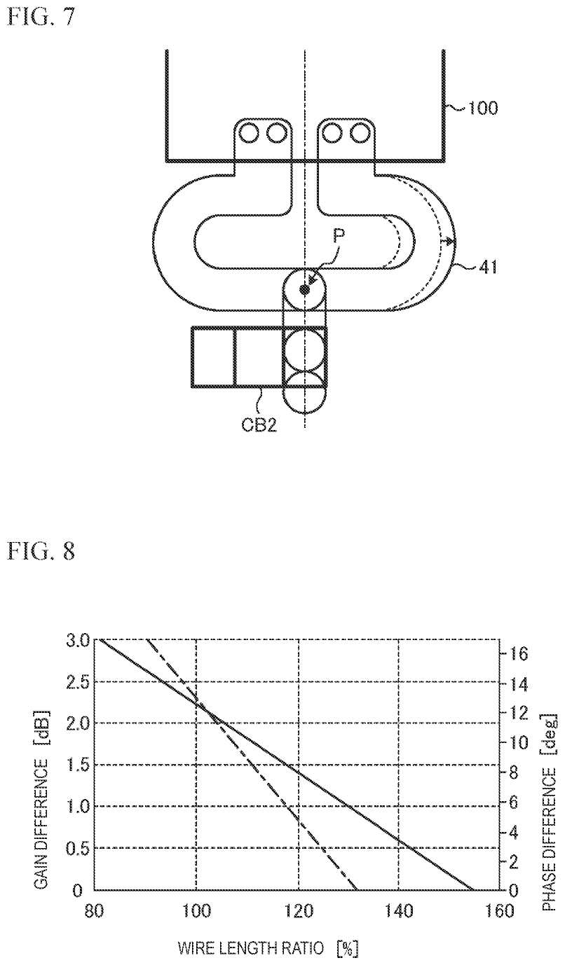

Note that the feature illustrated in FIG. 3A is one example, and a different feature can also be employed. FIG. 5 is a diagram illustrating an exemplary component layout that improves the asymmetry of differential signals in a power amplifying module according to a first modification example of the first embodiment. FIG. 6 is a diagram illustrating an improvement example of asymmetry of differential signals in the power amplifying module according to the first modification example of the first embodiment. FIG. 7 is a diagram illustrating an exemplary component layout that improves the asymmetry of differential signals in a power amplifying module according to a second modification example of the first embodiment. FIG. 8 is a diagram illustrating an improvement example of asymmetry of differential signals in the power amplifying module according to the second modification example of the first embodiment.

For example, as illustrated in FIG. 5, another feature may be employed in which by using the distance from one end of the inductor 41 to the power feed point P of the power supply potential VCC as the reference, the distance from the other end of the inductor 41 to the power feed point P of the power supply potential VCC is made shorter. As illustrated in FIG. 6, this enables reduction of the gain difference and the phase difference of differential signals and improvement of the asymmetry of differential signals. This enables suppression of the characteristic degradation caused by the asymmetry of differential signals.

Alternatively, as illustrated in FIG. 7, another feature may be employed in which by using the distance from the other end of the inductor 41 to the power feed point P of the power supply potential VCC as the reference, the distance from the one end of the inductor 41 to the power feed point P of the power supply potential VCC is made longer. As illustrated in FIG. 8, this enables reduction of the gain difference and the phase difference of differential signals and improvement of the asymmetry of differential signals. This enables suppression of the characteristic degradation caused by the asymmetry of differential signals.

### Second Embodiment

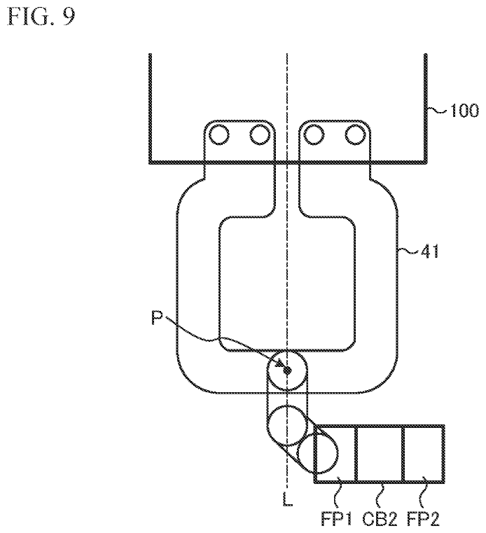

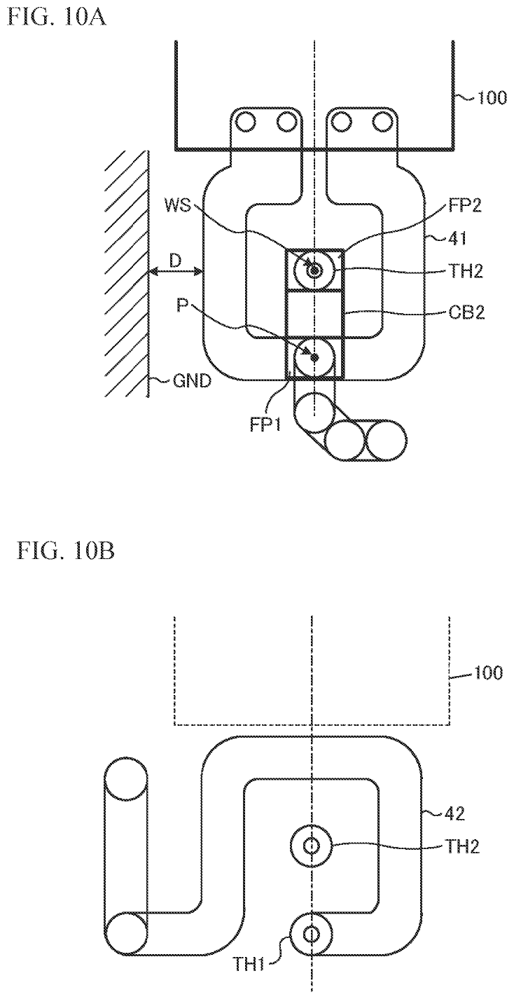

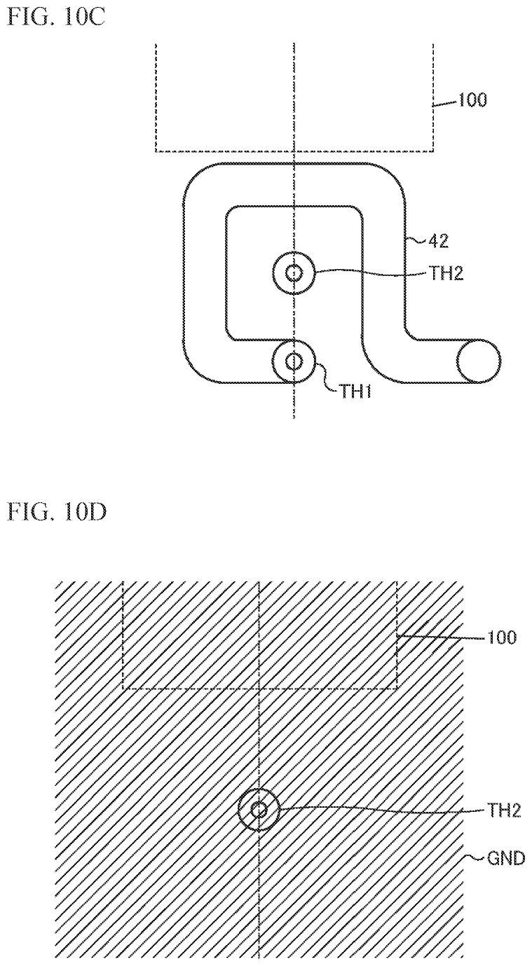

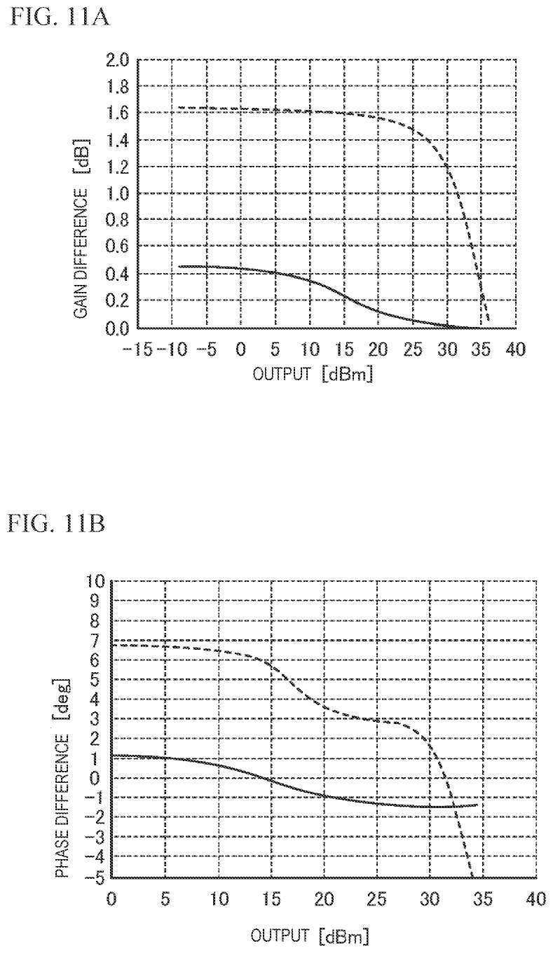

FIG. 9 is a diagram illustrating an improvement example of asymmetry of differential signals in a power amplifying module according to a comparative example. FIG. 10A, FIG. 10B, FIG. 10C, and FIG. 10D are each a diagram illustrating an exemplary component layout that improves the asymmetry of differential signals in a power amplifying module according to a second embodiment. FIG. 11A and FIG. 11B are each a diagram illustrating an improvement example of asymmetry of differential signals in the power amplifying module according to the second embodiment.

FIG. 10A illustrates a surface layer pattern of the substrate 2 on which the chip device 100 and SMD components are mounted, and FIG. 10B, FIG. 10C, and FIG. 10D illustrate inner layer patterns of the substrate 2. The inner layer patterns of FIG. 10B, FIG. 10C, and FIG. 10D are examples of the respective inner layer patterns in different layers. Note that FIG. 10D may be a pattern of a back surface of the substrate 2 on which the chip device 100 and SMD components are mounted.

As illustrated in FIG. 10A, in the second embodiment, the inductor 41 of the balun 4 is provided as the surface layer pattern of the substrate 2. Further, as illustrated in FIG. 10B and FIG. 10C, in the second embodiment, the inductor 42 of the balun 4 is provided as the inner layer patterns of the substrate 2. The inner layer pattern of the inductor 42 illustrated in FIG. 10B is connected to the inner layer pattern of the inductor 42 illustrated in FIG. 10C using a through hole TH1.

In the comparative example illustrated in FIG. 9, the distance from one end of the inductor 41 to the power feed point P of the power supply potential VCC is equal to the distance from the other end of the inductor 41 to the power feed point P of the power supply potential VCC. However, the position of the capacitor CB2 on the substrate 2 is deviated from the center line L that divides the wire length of the inductor 41 into two equal lengths. Because of this, there is a possibility of having asymmetry of differential signals.

In the second embodiment, the asymmetry of differential signals is improved by arranging two mounting terminals FP1 and FP2 of the capacitor CB2 in such a manner as to overlap the center line L dividing the wire length of the inductor 41 into two equal lengths in plan view seen from the surface layer side of the substrate 2.

Specifically, as illustrated in FIG. 10A, the mounting terminal FP1, which is one of the mounting terminals of the capacitor CB2, is arranged at a position that overlaps the power feed point P of the power supply potential VCC of the inductor 41 in plan view seen from the surface layer side of the substrate 2. Further, as illustrated in FIG. 10D, in an inner layer of the substrate 2, a reference potential (here, ground potential GND) pattern is provided at a position that overlaps a winding axis WS of the inductor 41 in plan view seen from the surface layer side of the substrate 2, and the mounting terminal FP2, which is the other of the mounting terminals of the capacitor CB2, is arranged in such a manner as to overlap the reference potential pattern (here, GND potential pattern). In other words, the reference potential pattern is electrically connected to the mounting terminal FP2, which is the other of the mounting terminals of the capacitor CB2. In the second embodiment, the reference potential pattern (here, GND potential pattern) is connected, by using a through hole TH2, to a GND pattern in the inner layer of the substrate 2 illustrated in FIG. 10D or a GND pattern on the back surface of the substrate 2 on which the chip device 100 and SMD components are mounted. Note that the mounting terminal FP1 corresponds to a “first mounting terminal” and the mounting terminal FP2 corresponds to a “second mounting terminal”.

FIG. 11A and FIG. 11B are each a diagram illustrating an improvement example of asymmetry of differential signals in a power amplifying module according to the second embodiment. In FIG. 11A, the horizontal axis represents the output of the differential amplifying circuit PA, and the vertical axis represents the gain difference between differential signals. In FIG. 11A, the dashed line depicts the gain difference between differential signals in the comparative example illustrated in FIG. 9, and the solid line depicts the gain difference between differential signals in the second embodiment illustrated in FIG. 10A. In FIG. 11B, the horizontal axis represents the output of the differential amplifying circuit PA, and the vertical axis represents the phase difference between differential signals. In FIG. 11B, the dashed line depicts the phase difference between differential signals in the comparative example illustrated in FIG. 9, and the solid line depicts the phase difference between differential signals in the second embodiment illustrated in FIG. 10A.

As illustrated in FIG. 11A and FIG. 11B, by arranging the capacitor CB2 in a symmetric manner on the center line L that divides the wire length of the inductor 41 into two equal lengths, it becomes possible to reduce the gain difference and the phase difference between the differential signals and improve the asymmetry of differential signals. This enables suppression of the characteristic degradation caused by the asymmetry of differential signals.

Further, as illustrated in FIG. 10A, in the case where the reference potential pattern (here, GND potential pattern) is provided around the inductor 41, the reference potential pattern (GND potential pattern) can be provided at a position separated from the inductor 41 by a predetermined distance D (for example, 0.2 mm) or more (for example, D 0.2 mm). This enables reduction of the impact on the symmetry of differential signals.

### Third Embodiment

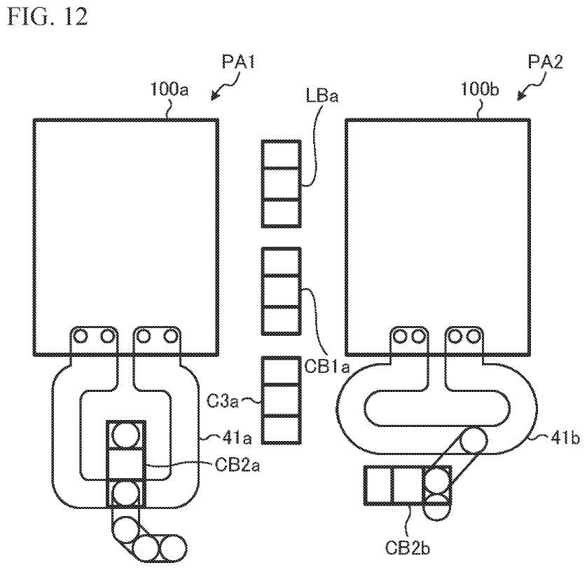

FIG. 12 is a diagram illustrating an exemplary layout of a plurality of differential amplifying circuits on a power amplifying module according to a third embodiment. FIG. 12 illustrates a configuration in which the configuration described in the first embodiment is applied to a differential amplifying circuit PA2 (second differential amplifying circuit) and the configuration described in the second embodiment is applied to a differential amplifying circuit PA1 (first differential amplifying circuit). The target of amplification of PA1 is, for example, Band “n79”, and the target of amplification of PA2 is, for example, Band “n77”.

FIG. 12 illustrates a chip device 100a, an inductor 41a, an inductor LBa, and capacitors C3a, CB1a, and CB2a of the differential amplifying circuit PA1. Further, FIG. 12 illustrates a chip device 100b, an inductor 41b, and a capacitor CB2b of the differential amplifying circuit PA2.

As illustrated in FIG. 12, in the configuration in which a plurality of differential amplifying circuits having different target bands of amplification is installed in a single power amplifying module 1, asymmetry of differential signals is likely to occur due to interference between the differential amplifying circuits or the like. Because of this, by arranging SMD components, such as, for example, the inductor LBa, the capacitors C3a and CB1a, and the like of the differential amplifying circuit PA1 between the differential amplifying circuit PA1 (first differential amplifying circuit) and the differential amplifying circuit PA2 (second differential amplifying circuit), it becomes possible to reduce the impact on the symmetry of differential signals due to the interference between the differential amplifying circuits or the like. The SMD components to be provided between the differential amplifying circuit PA1 and the differential amplifying circuit PA2 are not limited to the inductor LBa and the capacitors C3a and CB1a of the differential amplifying circuit PA1.

Note that in FIG. 12, the differential amplifying circuit PA1 (first differential amplifying circuit) has the feature in which the distance from one end of the inductor 41a to a power feed point of the power supply potential VCC is equal to the distance from the other end of the inductor 41a to the power feed point of the power supply potential VCC, and the differential amplifying circuit PA2 (second differential amplifying circuit) has the feature in which the distance from one end of the inductor 41b to the power feed point of the power supply potential VCC is different from the distance from the other end of the inductor 41b to the power feed point of the power supply potential VCC. However, the differential amplifying circuit PA1 (first differential amplifying circuit) may alternatively have the feature in which the distance from one end of the inductor 41a to the power feed point of the power supply potential VCC is different from the distance from the other end of the inductor 41a to the power feed point of the power supply potential VCC. Even in this case, the feature may be employed in which SMD components, such as, for example, the inductor LBa, the capacitors C3a and CB1a, and the like of the differential amplifying circuit PA1 are arranged between the differential amplifying circuit PA1 (first differential amplifying circuit) and the differential amplifying circuit PA2 (second differential amplifying circuit).

Further, the configurations and the numbers of stages of amplifiers of PA1 and PA2 are not limited to the configurations disclosed in the embodiments described above. For example, PA1 and PA2 may each includes a plurality of stages of amplifiers.

Further, the embodiments described above are provided to facilitate understanding of the present disclosure and are not to be construed as limiting the present disclosure. The present disclosure can be modified or improved without necessarily departing from its spirit, and the present disclosure also includes equivalents thereof.

The present disclosure can have the following configurations as described above or in place of the above.

(1) A power amplifying module according to one aspect of the present disclosure is a power amplifying module in which a plurality of differential amplifying circuits is mounted on a substrate, wherein each of the differential amplifying circuits includes a chip device that includes at least two amplifiers, each of the at least two amplifiers amplifying a differential signal, a balun that includes a primary side winding wire and a secondary side winding wire, both ends of the primary side winding wire being connected to an output of the chip device, and a capacitor provided between a power feed point of the primary side winding wire and a reference potential, and in at least one of the plurality of the differential amplifying circuits, a distance from one end of the primary side winding wire to the power feed point is different from a distance from an other end of the primary side winding wire to the power feed point.

According to this configuration, it becomes possible to reduce the gain difference and the phase difference of differential signals and improve the asymmetry of differential signals. This enables suppression of characteristic degradation caused by the asymmetry of differential signals.

(2) In the power amplifying module of the foregoing (1), in at least one of the plurality of the differential amplifying circuits, the power feed point is provided at a position deviated from a center line that divides a wire length of the primary side winding wire into two equal lengths.

According to this configuration, it becomes possible to reduce the gain difference and the phase difference of differential signals and improve the asymmetry of differential signals. This enables suppression of the characteristic degradation caused by the asymmetry of differential signals.

(3) In the power amplifying module of the foregoing (1) or (2), the capacitor includes a first mounting terminal and a second mounting terminal that electrically connect the substrate and the capacitor, and in at least one of the plurality of the differential amplifying circuits, the first mounting terminal and the second mounting terminal are arranged in such a manner as to overlap a center line that divides a wire length of the primary side winding wire into two equal lengths in plan view seen from a surface side of the substrate, on which the differential amplifying circuit is mounted.

According to this configuration, it becomes possible to reduce the gain difference and the phase difference of differential signals and improve the asymmetry of differential signals. This enables suppression of the characteristic degradation caused by the asymmetry of differential signals.

(4) The power amplifying module of the foregoing (3) further includes a reference potential pattern provided at a position that overlaps a winding axis of the primary side winding wire in plan view seen from the surface side of the substrate, on which the differential amplifying circuit is mounted, wherein in at least one of the plurality of the differential amplifying circuits, the first mounting terminal is arranged at a position that overlaps the power feed point of the primary side winding wire in plan view seen from the surface side of the substrate, on which the differential amplifying circuit is mounted, and the second mounting terminal is electrically connected to the reference potential pattern.

According to this configuration, it becomes possible to reduce the gain difference and the phase difference of differential signals and improve the asymmetry of differential signals. This enables suppression of the characteristic degradation caused by the asymmetry of differential signals.

(5) In the power amplifying module of the foregoing (1), the plurality of the differential amplifying circuits includes a first differential amplifying circuit and a second differential amplifying circuit, and in each of the first differential amplifying circuit and the second differential amplifying circuit, the power feed point is provided at a position deviated from a center line that divides a wire length of the primary side winding wire into two equal lengths.

According to this configuration, it becomes possible to reduce the gain difference and the phase difference of differential signals and improve the asymmetry of differential signals. This enables suppression of the characteristic degradation caused by the asymmetry of differential signals.

(6) In the power amplifying modules of the foregoing (1) to (5), in at least one of the plurality of the differential amplifying circuits, one end of the secondary side winding wire is connected to an output matching circuit, and a capacitor is provided between an other end of the secondary side winding wire and the reference potential.

According to this configuration, it becomes possible to provide impedance matching between the inductance value and the coupling coefficient of the balun.

(7) In the power amplifying modules of the foregoing (1) to (6), in at least one of the plurality of the differential amplifying circuits, a reference potential pattern is provided at a position separated from the primary side winding wire by a predetermined distance or more.

According to this configuration, it becomes possible to reduce the impact on the symmetry of differential signals.

(8) In the power amplifying modules of the foregoing (1) to (7), the plurality of the differential amplifying circuits includes a first differential amplifying circuit and a second differential amplifying circuit, and a plurality of SMD components is arranged between the first differential amplifying circuit and the second differential amplifying circuit.

According to this configuration, it becomes possible to reduce the impact on the symmetry of differential signals caused by interference between the differential amplifying circuits or the like.

According to the present disclosure, it becomes possible to realize a power amplifying module that enables suppression of characteristic degradation caused by asymmetry of differential signals.

What is claimed is:

1. A power amplifying module comprising a substrate on which a plurality of differential amplifying circuits is mounted,
wherein each of the differential amplifying circuits comprises:
a chip device comprising at least two amplifiers, each of the at least two amplifiers being configured to amplify a differential signal,
a balun comprising a primary side winding wire and a secondary side winding wire, both ends of the primary side winding wire being connected to an output of the chip device, and
a capacitor connected between a power feed point of the primary side winding wire and a reference potential, and
wherein in at least one of the plurality of the differential amplifying circuits, a distance from a first end of the primary side winding wire to the power feed point is different from a distance from a second end of the primary side winding wire to the power feed point.

2. The power amplifying module according to claim 1, wherein in at least one of the plurality of the differential amplifying circuits, the power feed point is at a position that is deviated from a center line, the center line dividing a wire length of the primary side winding wire into two equal lengths.

3. The power amplifying module according to claim 1, wherein the capacitor comprises a first mounting terminal and a second mounting terminal that electrically connect the substrate and the capacitor, and
wherein in at least one of the plurality of the differential amplifying circuits, the first mounting terminal and the second mounting terminal overlap a center line, the center line dividing a wire length of the primary side winding wire into two equal lengths in plan view as seen from a surface side of the substrate.

4. The power amplifying module according to claim 3, further comprising:
a reference potential pattern at a position that overlaps a winding axis of the primary side winding wire in plan view as seen from the surface side of the substrate, wherein in at least one of the plurality of the differential amplifying circuits, the first mounting terminal is at a position that overlaps the power feed point of the primary side winding wire in plan view as seen from the surface side of the substrate, and
wherein the second mounting terminal is electrically connected to the reference potential pattern.

5. The power amplifying module according to claim 1, wherein the plurality of the differential amplifying circuits comprises a first differential amplifying circuit and a second differential amplifying circuit, and
wherein in each of the first differential amplifying circuit and the second differential amplifying circuit, the power feed point is at a position that is deviated from a center line, the center line dividing a wire length of the primary side winding wire into two equal lengths.

6. The power amplifying module according to claim 1, wherein in at least one of the plurality of the differential amplifying circuits, a first end of the secondary side winding wire is connected to an output matching circuit, and a capacitor is connected between a second end of the secondary side winding wire and the reference potential.

7. The power amplifying module according to claim 1, wherein in at least one of the plurality of the differential amplifying circuits, a reference potential pattern is at a position separated from the primary side winding wire by at least a predetermined distance.

8. The power amplifying module according to claim 1, wherein the plurality of the differential amplifying circuits comprises a first differential amplifying circuit and a second differential amplifying circuit, and a plurality of surface mounted device components is arranged between the first differential amplifying circuit and the second differential amplifying circuit.
